(19) United States
(12) Patent Application Publication
(10) Pub. No.: US 2003/0113964 A1
(43) Pub. Date: Jun. 19, 2003

(54) Method for forming a storage node

(76) Inventors: Sang-tae Choi, Seoul-shi (KR); Il-hyung Kim, Seoul-shi (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/318,744

(22) Filed: Dec. 13, 2002

(30) Foreign Application Priority Data
Dec. 15, 2001 (KR) 2001-79768

(51) Int. Cl. H01L 21/8242; H01L 21/336; H01L 27/108; H01L 29/76; H01L 29/94; H01L 31/119

(52) U.S. Cl. 438/239; 257/296

(57) ABSTRACT

A method for forming a storage node using photoresist is described. The method can form a storage node pattern in a rectangular shape which allows for deep etching because it has a smaller slope than a conventional elliptical pattern by employing a double exposure method which firstly forms a portion corresponding to the major axis of the storage node using a negative photoresist and secondly forms a portion corresponding to the minor axis of the storage node using a positive photoresist.

### BACKGROUND

1. Technical Field

A method for forming a storage node pattern for a semiconductor device is disclosed that has a rectangular shape which allows for deep etching because it has a smaller slope than a conventional elliptical pattern by employing a double exposure method which first forms a portion corresponding on the major axis of the storage node using a negative photoresist and then forms a portion corresponding to the minor axis of the storage node using a positive photoreist.

2. Description of the Related Art

Generally, as the degree of integration of a semiconductor device such as a dynamic random access memory (DRAM) increases, the area occupied by the memory cell is reduced. However, since a predetermined capacitance per unit memory cell must be secured to operate the semiconductor device, it is still required that a high process technique be developed and the reliability of the semiconductor device be secured for minimizing the area occupied by a capacitor while maintaining the capacitance required for operating the memory cell.

FIGS. 1a and 1b are cross-sectional views showing a storage node pattern in accordance with the prior art.

As shown in FIG. 1a, a storage node pattern as shown in FIG. 1b is formed by using a first photoresist in a sloped elliptical shape in accordance with the prior art.

However, there is a problem in securing a desired capacitance of a capacitor since the patterning of the semiconductor device and securing of the major axis of the storage node becomes difficult as the pattern of the photoresist becomes finer due to the high integration of the semiconductor device.

Although the prior art utilizes a technique to secure a capacitance by controlling a depth of etching since the insurance of area is difficult, there is still another problem in securing a uniformity or a process margin in accordance with the fining of the photoresist pattern.

### SUMMARY OF THE DISCLOSURE

To solve the above mentioned problems, methods for forming a storage node pattern in a rectangular shape are disclosed which allows for deep etching because it has a smaller slope than a conventional elliptical pattern by employing a double exposure method which first forms a portion corresponding to the major axis of the storage node using a negative photoresist and then forms a portion corresponding to the minor axis of the storage node using a positive photoresist.

One disclosed method for forming a storage node using a photoresist, comprises: preparing a semiconductor substrate with a substructure of a predetermined shape; forming a first photoresist on the semiconductor substrate; forming a first photoresist pattern by patterning the first photoresist to form the major axis of the storage node; forming a second photoresist on the first photoresist pattern; forming a second photoresist pattern by patterning the second photoresist to form the minor axis of the storage node; and forming the storage node in a rectangle shape by a double exposure method using the first and second photoresist patterns.

In an embodiment, the first photoresist pattern for the major axis is larger than the second photoresist pattern for the minor axis.

Preferably, the first photoresist is made of a negative photoresist and the second photoresist is made of a positive photoresist because the negative photoresist does not dissolve in a solvent contained in the positive photoresist when reacted with the positive photoresist.

Preferably, the second photoresist pattern for the minor axis is finer than the first photoresist pattern for the major axis.

### BRIEF DESCRIPTION OF THE DRAWINGS

The above features and advantages of the disclosed embodiments will become more apparent from the following detailed description when taken in conjunction with the accompanying drawings, in which:

FIGS. 1a and 1b are cross-sectional views showing a storage node pattern in accordance with the prior art;

FIG. 2 schematic view showing photoresist patterns for patterning a storage node in accordance with a preferred embodiment of the present invention; and

FIGS. 3a and 3b are cross sectional views showing storage nodes in accordance with the preferred embodiment of the present invention.

### DETAILED DESCRIPTION OF THE PRESENTLY PREFERRED EMBODIMENTS

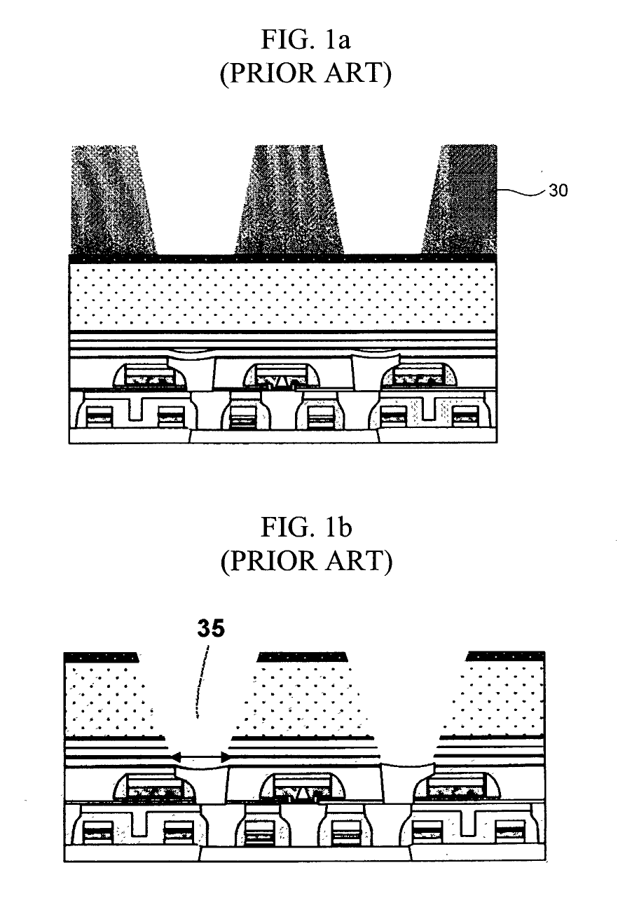

A preferred embodiment will now be described with reference to the accompanying drawings. The preferred embodiment is intended to illustrate the principles of this disclosure, but not to limit the scope of the claimed invention. In the following description, same drawing reference numerals are used for the same elements as those of the prior art as illustrated in FIGS. 1a-1b.

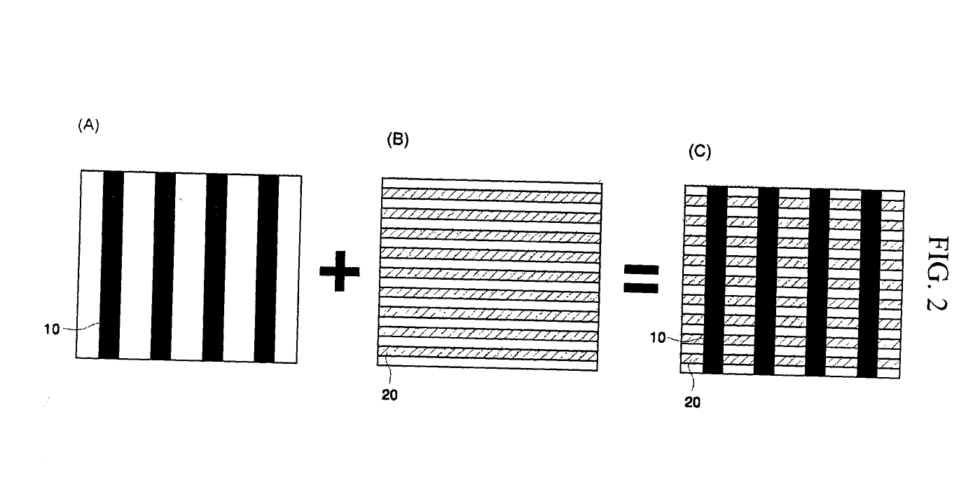

FIG. 2 shows photoresist patterns for patterning a storage node in accordance with this disclosure, in which (A) represents a first photoresist pattern 10 of a negative photoresist for patterning the portion corresponding to the major axis of the storage node, (B) represents a second photoresist pattern 20 of a positive photoresist for patterning the portion corresponding to the mionr axis of the storage node, and (C) represents a photoresist pattern for forming the storage node for double exposure with the first and second photoresist patterns 10 and 20 being crossed.

At this time, it is preferable that the first photoresist pattern 10 for the major axis be larger than the second photoresist pattern 20 for the minor axis in size because it has a relatively smaller resolution than the second photoresist pattern 20, i.e., the positive photoresist pattern. In accordance with the preferred embodiment of the present invention, the second photoresist pattern 20 is finer than the first photoresist pattern 10. Also, it is preferable that the first photoresist pattern 10 be made of a negative photoresist because the negative photoresist does not dissolve in the solvent contained in the positive photoresist when reacted with the positive photoresist.

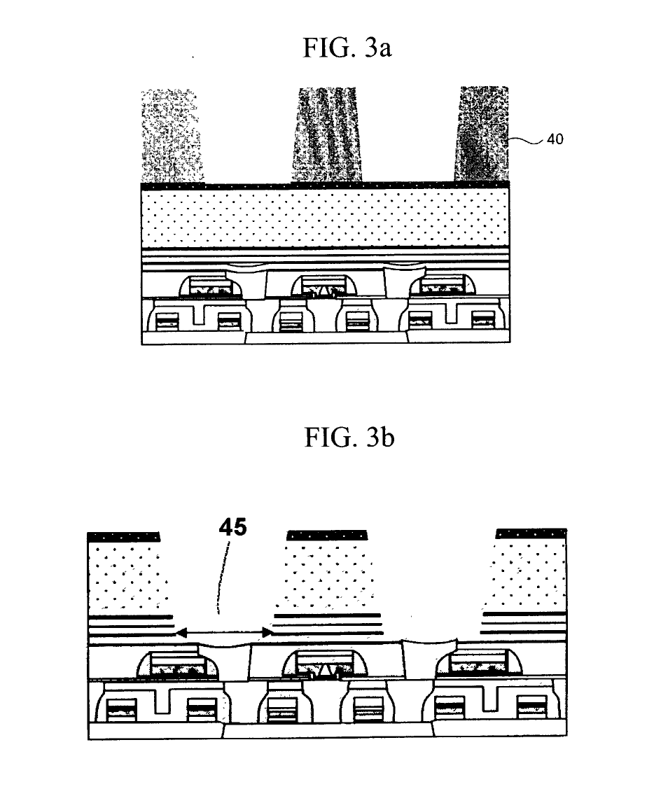

FIGS. 3a and 3b are cross-sectional views showing a storage node fabricated in accordance with the disclosed methods.

A preferred embodiment will now be described. First, a semiconductor substrate with a substructure of a predetermined shape is prepared and the first photoresist is formed on the semiconductor substrate. Next, the first photoresist is patterned into the first photoresist pattern 10 to form the major axis of the storage node and the second photoresist is formed on the first photoresist pattern 10 to form the minor axis of the storage node. After the second photoresist is patterned into the second photoresist pattern 20, the storage node in the shape of a rectangle is formed by a double exposure method using the first and second photoresist patterns 10 and 20.

As shown in FIG. 3a, a storage node 45 as shown in FIG. 3b capable of securing a critical dimension (CD) at a bottom portion thereof is formed by patterning with a photoresist pattern 40 having a small slope in the form of a rectangle by using the photoresist patterns 10 and 20 shown in FIG. 2.

While the invention has been shown and described with reference to the preferred embodiment thereof, it will be understood by those skilled in the art that various changes in form and details may be made therein without departing from the spirit and scope of the invention as defined by the appended claims.

As described above, the present invention can form a storage node pattern in rectangular shape which allows for deep etching because it has a smaller slope than a conventional elliptical pattern by employing a double exposure method which first forms a portion corresponding to the major axis of the storage node using a negative photoresist and then forms a portion corresponding to the minor axis of the storage node using a positive photoresist. Thusly the capacitance of a capacitor can be increased and the reliability of a semiconductor device can be secured as the depth of etching becomes higher than the conventional elliptical pattern.

What is claimed is:

1. A method for forming a storage node using photoresist comprises:
preparing a semiconductor substrate with a substructure;
forming a first photoresist on the semiconductor substrate;
forming a first photoresist pattern by patterning the first photoresist to form the major axis of the storage node;
forming a second photoresist on the first photoresist pattern;
forming a second photoresist pattern by patterning the second photoresist to form the minor axis of the storage node; and
forming the storage node in a shape of rectangle by a double exposure method using the first and second photoresist patterns.

2. The method of claim 1, wherein the first photoresist pattern is made of a negative photoresist.

3. The method of claim 1, wherein the second photoresist pattern is made of a positive photoresist.

4. The method of claim 1, wherein the first photoresist pattern for the major axis is relatively larger than the second photoresist pattern for the minor axis in size.

5. The method of claim 1, wherein the second photoresist pattern for the minor axis is finer than that of the first photoresist pattern for the major axis.
